(19) United States
(12) Patent Application Publication
(10) Pub. No.: US 2025/0226014 A1
(43) Pub. Date: Jul. 10, 2025

(54) OUTPUT LATCH AND AMPLIFIER

(71) Applicant: NVIDIA Corp., Santa Clara, CA (US)

(72) Inventors: Lalit Gupta, FREMONT, CA (US); Jason Golbus, Palo Alto, CA (US); Jesse San-Jey Wang, Santa Clara, CA (US)

(73) Assignee: NVIDIA Corp., Santa Clara, CA (US)

(21) Appl. No.: 18/407,807

(22) Filed: Jan. 9, 2024

(51) Int. Cl. G11C 7/10

(52) U.S. Cl. CPC G11C 7/106

(57) ABSTRACT

Readout logic for bit-storing cells of a machine memory wherein the bit-storing cells comprise first read/write voltage domain crossings includes a read latch coupled to the bit-storing cell via a read bitline and the read latches include second read/write voltage domain crossings configured in pull-down networks of the read latches.

### BACKGROUND

A memory bank is a unit of data storage in electronics, which is hardware-dependent. In a computer, for example, the memory bank may be determined by the physical organization of the hardware memory. In a typical static random-access memory (static RAM or SRAM), a bank may include multiple rows and columns of storage units, and is usually spread out across circuits. An SRAM is a type of semiconductor memory that uses bi-stable latching circuitry (e.g., a flip-flop or a portion thereof) to store each bit. In a single read or write operation, generally only one bank is accessed. Certain types of memory may implement a register file.

A common feature of most modern memories is the use of a hierarchical bitline arrangement in which, instead of a single bitline that runs the complete height of a column of memory cells and connects to each cell in the column, a multi-level structure is used. Effectively, a single bitline is broken up into multiple “local bitlines”, each of which connects to the memory cells in a part of the column. A “global bitline” also runs the height of the column, and is connected to the local bitlines via switches. “Global bitline” refers to a bitline that spans groups of memory cells each with local bitlines. “Memory cell” refers to any circuit that stores a binary value. The memory controller connects to the global bitline, and not directly to the local bitlines. “Memory controller” refers to logic that generates control signals for reading, writing, and managing memory cells. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). During a memory access, only a local bitline in the relevant part of the column is connected (via its local-to-global switch) to the global bitline.

Often bit cell based register files are typically organized in multiple array banks. Each bank may be organized with multiple bit-cells on a local bitline. Generally, a bitline conveys information to or from a memory cell when a memory access (e.g., read, write) occurs.

Generally, a read bitline is attached to two circuits. The first circuit comprises a keeper or pull-up device which serves the purpose of retaining the state of the bitline when it is not actively driven. The second circuit comprises a separate precharge device that pulls the bitline “high” or up after the evaluation phase of the memory access completes.

Often the demands placed on the bitline cause issues with accessing the memory cells. For example, the keeper device is required to work across a wide range of process, voltage and temperature (PVT) variations, and prevent the bitline from leaking current and transitioning to “low” when it is not desired. In another example, a contention may exist between the keeper device (pulling the bitline “high”) and a bank's bitline pull-down device (pulling the bitline “low”).

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts a memory controller in accordance with one embodiment.

FIG. 2 depicts a timing diagram in accordance with one embodiment.

FIG. 3 depicts read-out logic for a bit-storing cell in one embodiment.

FIG. 4 depicts an example of a bit-storing cell and associated logic to read the values stored in the cells out to a read bitline. “Bit-storing cell” is another term for a memory cell, but also encompasses value-storing circuits such as latches and registers.

FIG. 5 depicts a read latch in one embodiment.

FIG. 6 depicts a read latch in another embodiment.

FIG. 7 depicts an example of a memory system utilizing bit lines traversing multiple memory banks.

FIG. 8 depicts control signals for read logic of a machine memory system in one embodiment.

FIG. 9 depicts clocking logic for a machine memory system in one embodiment.

FIG. 10 depicts clocking logic for a machine memory system in another embodiment.

FIG. 11 depicts applications of a memory system utilizing the disclosed mechanisms in accordance with one embodiment.

### DETAILED DESCRIPTION

Embodiments of a read latch for machine memories are described. The disclosed read latch implementations exhibit improved performance and lower power consumption compared to conventional read latch structures of substantially the same circuit area. Power savings and noise margins are especially improved at processes at which vddr>>vddw.

Circuit embodiments are disclosed wherein a bit-storing cell includes a first read/write voltage domain crossing and a read latch is coupled to the bit-storing cell via a read bitline. “Read/write voltage domain crossing” refers to a gate or gates of a circuit net where different terminals of the gate(s) are configured to operate in both the read voltage domain and the write voltage domain. “Read voltage domain” herein refers to the voltage domain (range of high and low voltage levels) in which readout logic of a memory system operates. “Write voltage domain” refers to herein refers to the voltage domain (range of high and low voltage levels) in which the bit-writing and storing logic of a memory system operates. The read latch includes a second read/write voltage domain crossing.

In one aspect, the second read/write voltage domain crossing is configured in a pull-down network of the read latch. “Pull-down network” refers to gates and connections within a circuit net that operate to pull down the voltage at a node of the circuit net to logic ground. The pull-down network is configured on a latching node of the read latch, and a keeper circuit may be coupled between the read bitline and the latching node. “Latching node” refers to the node within a latch circuit net where the signal applied to the latch input is captured and stored when the latch is toggled (e.g., by a clock). In another aspect, the second read/write voltage domain crossing is configured at the terminals of a single transistor of the pull-down network.

Other technical features may be readily apparent to one skilled in the art from the following figures, descriptions, and claims.

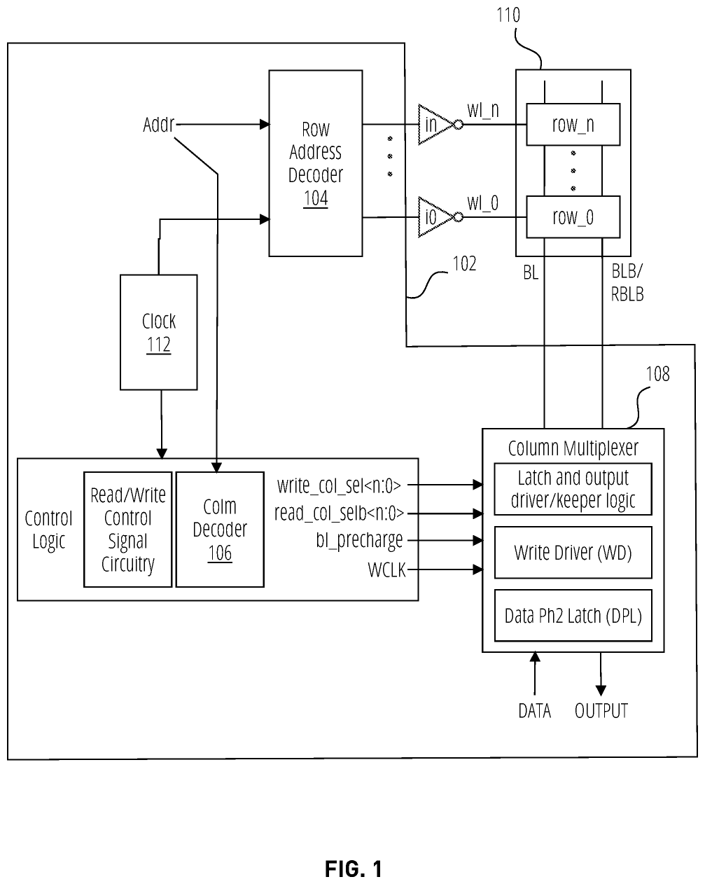

FIG. 1 depicts a memory controller 102 in one embodiment. A row address decoder 104 translates a memory address into a row (word line) selection, and a column decoder 106 translates the address into column (bitline) selection(s). The bit-storing cells along the selected row and column are read by the column multiplexer 108, which includes latches for data read from the machine memory 110, keeper logic (described below), and logic for writing values into the bit-storing cells of the machine memory 110. These operations may be performed synchronously and thus coordinated by a clock 112.

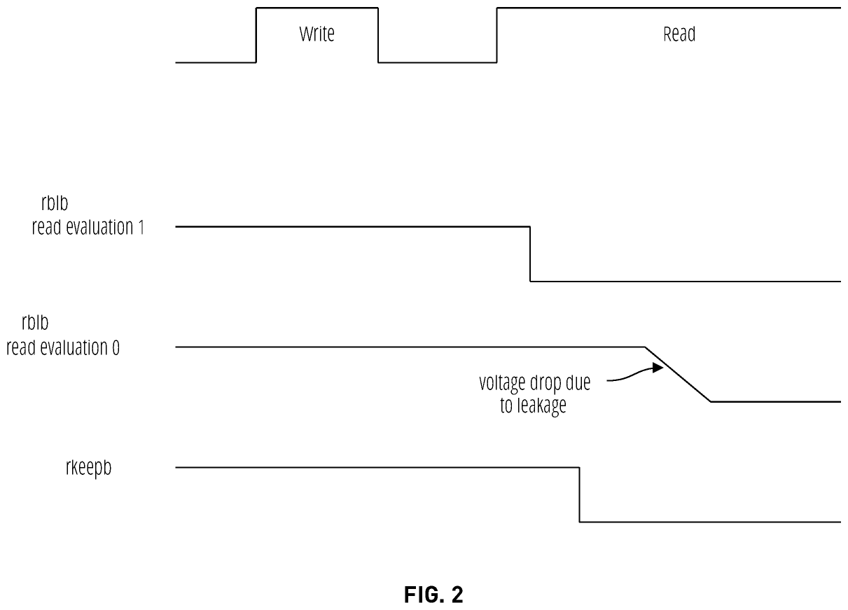

FIG. 2 depicts a timing diagram for read evaluation 1 and read evaluation 0 with respect to a keeper signal for a bitline (rblb). For read evaluation 1, the keeper signal is triggered soon after the discharge of rblb, so as not to interfere with the discharge and create an erroneous reading. During read evaluation 0 rblb should ideally remain charged to VDD but due to leakage it may discharge to the point that an erroneous “1” value is detected in the evaluated cell. If the keeper signal is not triggered, rblb will start to discharge due to leakage (as depicted), which may, depending on latencies in the system, lead to erroneous readings. Hence the timing of the rblb keeper signal is critical. Because leakage and other factors may vary over large circuit areas due to process, timing, and voltage variations, among other things, the timing of the keeper signal becomes highly constrained.

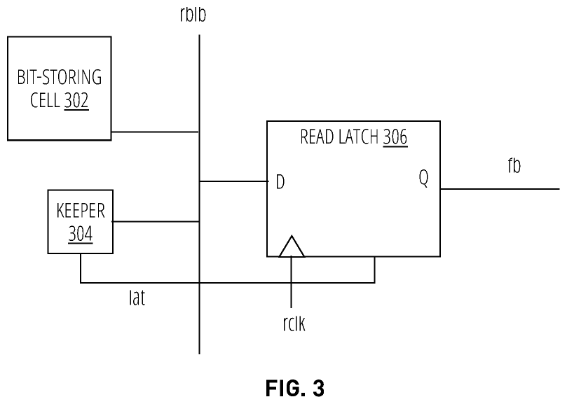

FIG. 3 depicts read-out logic for a bit-storing cell 302 in one embodiment. The read-out logic comprises a keeper circuit 304 and a read latch 306. For simplicity of description, other logic that may be utilized in various embodiments for read-out of values from the bit-storing cell 302 is not depicted. During a read evaluation, the keeper circuit 304 may be activated to maintain a floating voltage level on rblb to meet the setup and hold time of the read latch 306.

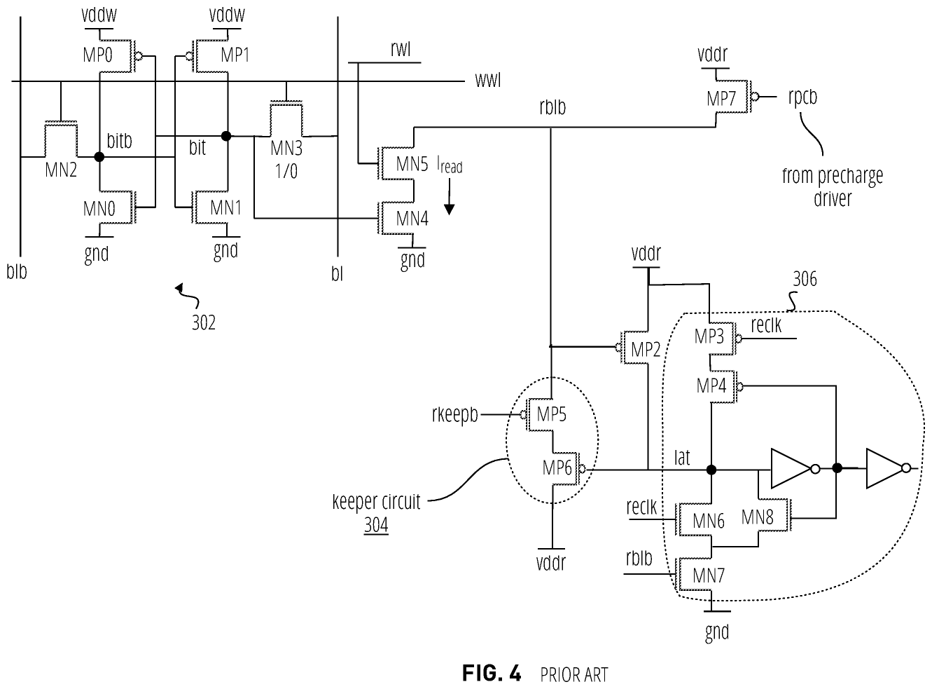

FIG. 4 depicts an example of a bit-storing cell and associated logic to read the values stored in the cells out to a read bitline (rblb). The bit-storing cell comprises NMOS transistors MN0-MN5 and PMOS transistors MP0 and MP1. A bit value bit and its complement bitb are stored in the bit-storing cell, the core of which comprises header transistors MP0 and MP1, and footer transistors MN0 and MN1. The writing of bits into the bit-storing cell from the bit lines bl and blb is controlled by the write word line (WWL) and access transistors MN2 and MN3. The read word line (RWL) and access transistors MN4 and MN5 control the reading of the stored bit to the read bit line rblb, which is pre-charged for the read via PMOS transistor MP7.

The transistor MN4 is coupled to the voltage domain vddw of the bit-storing cell 302, and to the voltage domain vddr of the readout logic. When there is a large gap between these supply voltages, particularly at the process corner where vddw is at a minimum rated level and vddr is at a maximum rated level (vddw<<vddr), the transistor MN4 generates a reduced channel current I_{read} during a read evaluation operation, which in turn increases the clock-to-Q time of the read latch 306.

The read bit line rblb is coupled to a keeper circuit 304. The keeper circuit 304 comprises PMOS transistors MP5 and MP6. The read bit line rblb is further coupled to an output read latch 306 via PMOS transistor MP2. Signal rpcb is applied to pre-charge rblb and the keeper signal rkeepb maintains the pre-charge long enough for the bit value on rblb to settle at node lat (i.e., the setup and hold time) for capture by the read latch 306 upon receipt of the read clock reclk. In this example the read latch 306 comprises NMOS transistors MN6-MN8 and PMOS transistors MP3 and MP4.

At the process corner vddw<<vddr, the lower levels of I_{read} through transistor MN4 may necessitate a reduction in the frequency of the read clock rdclk to account for the lengthened settling time of the read-out bit value at node lat. This can result in slower, lower bandwidth memory device performance.

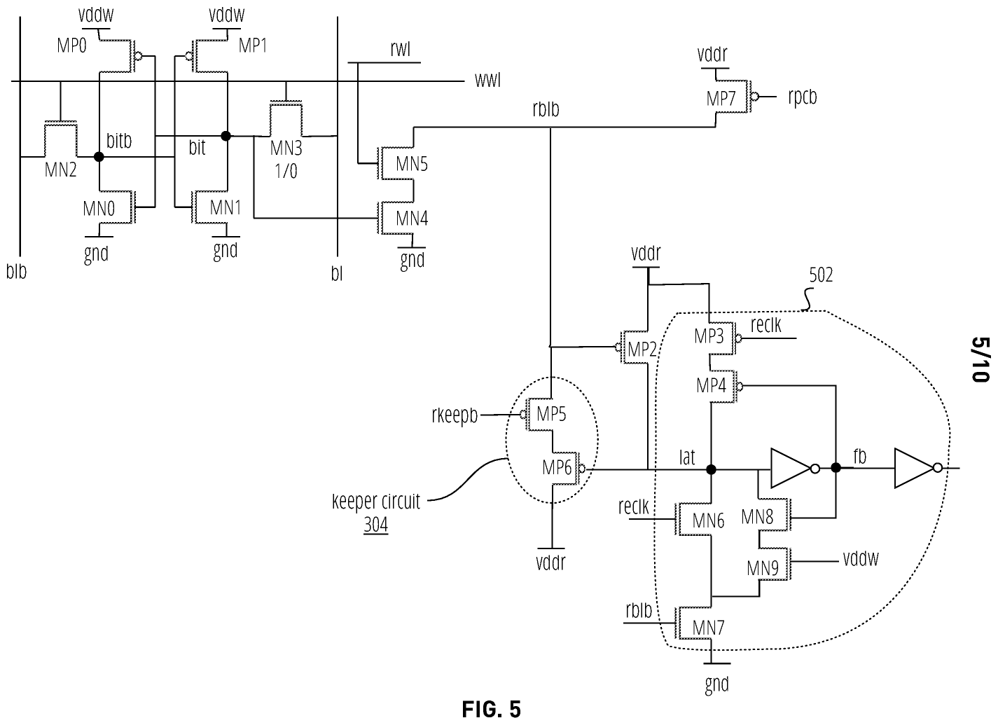

Counterintuitively, the impact of the I_{read} reduction arising from the voltage domain crossing at transistor MN4 may be mitigated in one embodiment by configuring another voltage domain crossing within the read latch 502. In the embodiment depicted in FIG. 5, the source and drain of transistor MN9 are implemented in domain vddr of the read logic and the gate of MN9 is implemented in the domain vddw of the bit-storing cell 302.

The lat node of the read latch 502 is coupled to a pull-up network comprising transistors MP2, MP3, and MP4, and to a pull-down network comprising transistors MN6, MN7, MN8, and MN9.

Transistor MN6 shuts off after resetting the read latch 502, and the channel current Iₗₐₜ through MN9 is modulated by vddw. As I_{read} decreases with changes to vddw, the current through MN8 and MN9 decreases due to the gating of MN9 with vddw. The trip point of the read latch 502 shifts due to the lat node discharging more slowly, such that the clock-to-Q time of the read latch 502 decreases in accordance with the decrease in I_{read}.

Configurations in accordance with this embodiment may achieve a substantial improvement of the clock-to-Q delay of the read latch 502, especially at process node vddw<<vddr. Negative impact on read bandwidth (e.g., due to increases in clock-to-Q of the read latch 502) arising from a higher slew of I_{read} at vddw<<vddr (and more generally for any vddw<vddr process) may be mitigated. An additional benefit is that the timing window for the keeper circuit 304 remains relatively stable across different vddr-vddw processes.

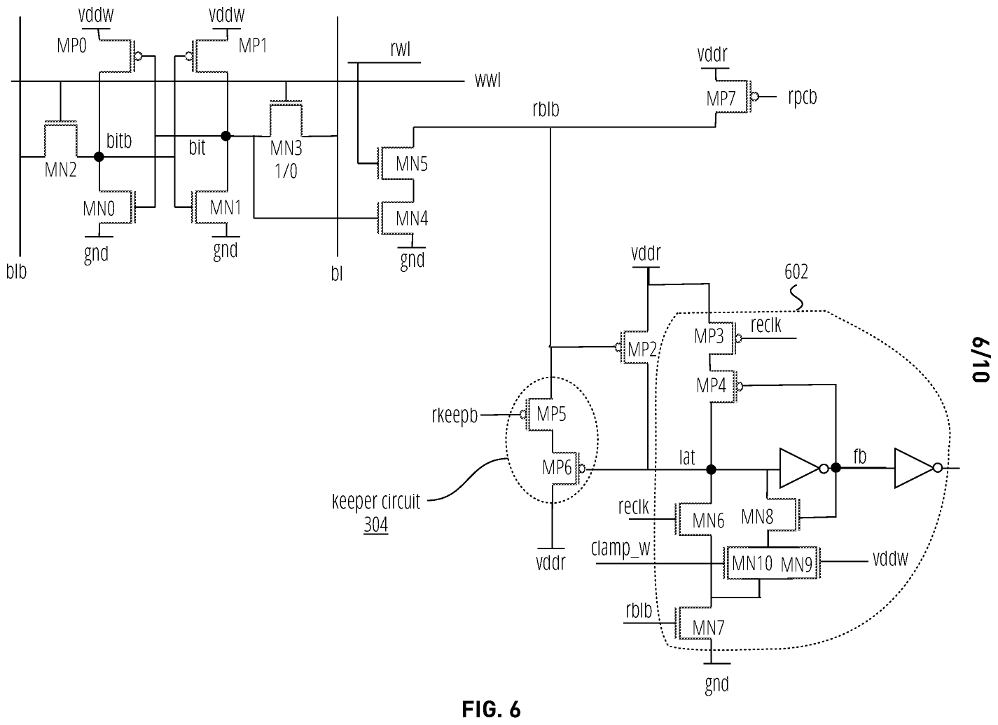

Under certain operating conditions, such as when lat=0, fb=vddr, rblb=vddr, reclk=0, rkpb=vddr, and vddw collapses below operational margins, the embodiment of FIG. 5 may experience undesirable operational behavior. FIG. 6 depicts a read latch 602 in another embodiment to account for this situation. An additional transistor MN10 is included in the pull-down network on the lat node. The circuit is configured to apply a clamping signal clamp_w along with vddw to the gates of the parallel configuration of transistors MN10 and MN9, respectively, of the pull-down network.

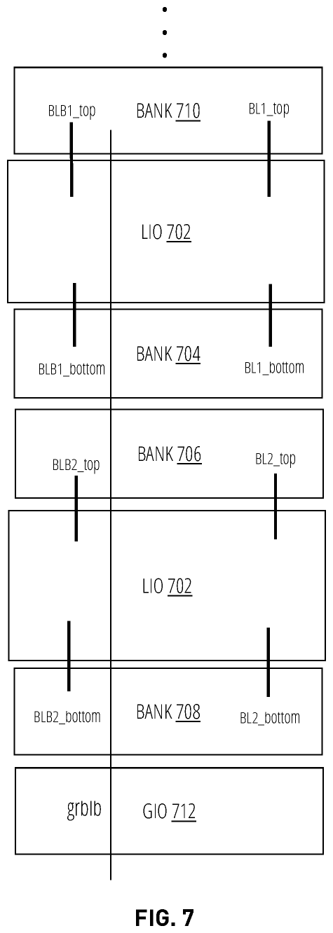

FIG. 7 depicts an example of a multi-bank memory system utilizing a plurality of local IO drivers 702 and local bit lines. The depicted example comprises memory banks 704, 706, 708, 710, but there may be more or fewer than this, depending on the implementation. In this example, each local IO driver 702 drives a bit line that is local to (does not extend beyond) a pair of the memory banks.

The local IO drivers 702 share common IO logic 712 (i.e., GIO). In some memory technologies, a local bit line may extend through more than two memory banks, but generally less than all of the memory banks in the memory. A global read bit line grblb may extend from the memory controller (e.g., column multiplexer 108) to traverse the memory banks, wherein it splits off into local read bit lines rblb.

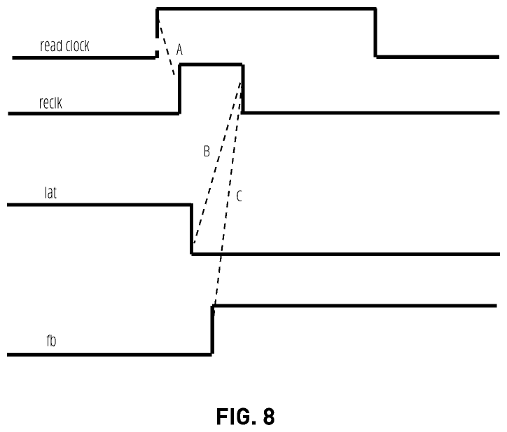

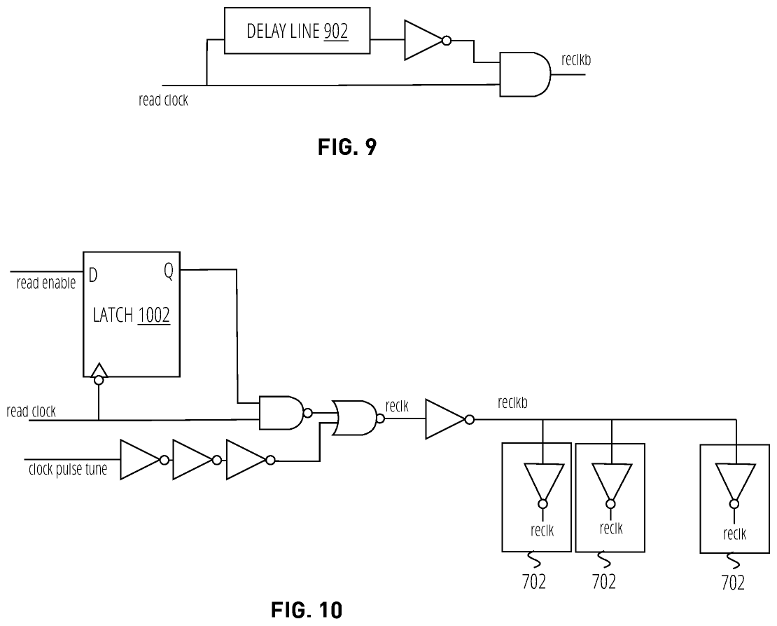

FIG. 8 depicts control signals for read logic of a machine memory system in one embodiment. The memory controller 102 generates a read clock signal that results in a clock signal reclk to the read latches in the local IO drivers 702 for the memory banks of the machine memory 110. The value read out of the selected bit-storing cell 302 settles at the lat node, resulting in a latched value fb. In the depicted example, reclk is configured to rise to at least 80% of its full-swing value at least four gate delay intervals after read clock reaches 80% of its full-swing value (see label “A” in FIG. 8). The voltage at the lat node should settle to 20% or less of its full-swing value before reclk falls 80% of its full-swing value (see label “B” in FIG. 8). The latched value read from the bit-storing cell 302 should settle to 80% or more of its full-swing value before reclk falls 80% of its full-swing value (see label “C” in FIG. 8). The width and timing of the reclk signal to satisfy timing conditions such as depicted in FIG. 8 may be configured using logic such as that depicted in FIG. 9 and FIG. 10.

FIG. 9 depicts clocking logic for a machine memory system in one embodiment. The reclk signal is generated by combining the read clock signal at an AND logic gate with a delayed and inverted version of itself. The delay is implemented for example using a delay line 902, e.g., a string of inverters. The delay may be a fixed amount, or may be tunable, in manners known in the art. Both the timing and the width of the reclk pulse to trigger the read latch are determined by the delay configured in the delay line 902.

FIG. 10 depicts clocking logic for a machine memory system in another embodiment. The reclk signal is generated by combining the read clock signal at a NAND logic gate with a delayed and version of the read enable signal asserted by the memory controller 102 and captured by a latch 1002. By utilizing a latch 1002 with similar clock-to-Q delay as the read latches, the configured delay in reclk accounts for the clock-to-Q delay of the read latches in the local IO drivers 702.

Output of the NAND gate is input to a NOR gate. Timing and width of the reclk pulse output from the NOR gate is configured for example using a delay line, e.g., a string of inverters. The delay may be a fixed amount, or may be tunable, in manners known in the art. Both the timing and the width of the reclk pulse to trigger the read latches are determined by the delay configured in the delay line and the latch 1002.

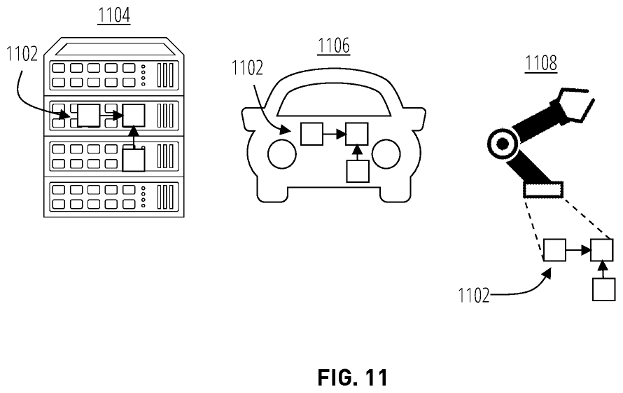

FIG. 11 depicts exemplary scenarios for use of a memory system 1102 utilizing the disclosed mechanisms. A memory system 1102 may be utilized in a computing system 1104 (e.g., a server/data center system), a vehicle 1106, and a robot 1108, to name just a few examples. The memory system 1102 may comprise a plurality of memory banks, a memory controller, and local IO drivers for the memory banks in accordance with the embodiments described herein, for example.

### LISTING OF DRAWING ELEMENTS

102 memory controller
104 row address decoder
106 column decoder
108 column multiplexer
110 machine memory
112 clock
302 bit-storing cell
304 keeper circuit
306 read latch
502 read latch
602 read latch
702 local IO driver
704 bank
706 bank
708 bank
710 bank
712 common IO logic
902 delay line
1002 latch
1102 memory system
1104 computing system
1106 vehicle
1108 robot

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the intended invention as claimed. The scope of inventive subject matter is not limited to the depicted embodiments but is rather set forth in the following Claims.

What is claimed is:

1. A circuit comprising:
a bit-storing cell comprising a first read/write voltage domain crossing;
a read latch coupled to the bit-storing cell via a read bitline; and
the read latch comprising a second read/write voltage domain crossing.

2. The circuit of claim 1, wherein the second read/write voltage domain crossing is configured in a pull-down network of the read latch.

3. The circuit of claim 2, wherein the second read/write voltage domain crossing is configured at the terminals of a single transistor of the pull-down network.

4. The circuit of claim 2, wherein the pull-down network is configured on a latching node of the read latch.

5. The circuit of claim 4, further comprising:
a keeper circuit coupled between the read bitline and the latching node.

6. The circuit of claim 7, wherein the first read/write voltage domain crossing is configured at an interface of the bit-storing cell to the read bitline.

7. A circuit comprising:
a bit-storing cell configured to operate in a write voltage domain;
a read latch coupled to the bit-storing cell via a read bitline, the read bitline configured to operate in a read voltage domain different than the write voltage domain; and
a first read/write voltage domain crossing configured in the read latch.

8. The circuit of claim 7, wherein the first read/write voltage domain crossing is configured in a pull-down network of the read latch.

9. The circuit of claim 8, wherein the first read/write voltage domain crossing is configured at the terminals of a single transistor of the pull-down network.

10. The circuit of claim 8, wherein the pull-down network is configured on a latching node of the read latch.

11. The circuit of claim 10, further comprising:
a keeper circuit coupled between the read bitline and the latching node.

12. The circuit of claim 7, wherein the bit-storing cell comprises a second read/write voltage domain crossing at an interface to the read bitline.

13. A memory system comprising:
a memory bank comprising a plurality of bit-storing cells operating in a write voltage domain;
the bit-storing cells coupled to a read bitline operating in a read voltage domain different than the write voltage domain;
a read latch coupled to the read bitline;
a keeper circuit coupled between the read bitline at a latching node of the read latch; and
a first read/write voltage domain crossing coupled to the latching node.

14. The circuit of claim 13, wherein the first read/write voltage domain crossing is configured in a pull-down network of the read latch.

15. The circuit of claim 14, wherein the first read/write voltage domain crossing is configured at the terminals of a single transistor of the pull-down network.

16. The circuit of claim 14, wherein the bit-storing cell comprises a second read/write voltage domain crossing at an interface to the read bitline.

17. A process comprising:
configuring a bit-storing cell to operate in a write voltage domain of a memory circuit;
configuring a read latch coupled to the bit-storing cell via a read bitline to operate in a read voltage domain different than the write voltage domain; and
configuring a read/write voltage domain crossing in the read latch.

18. The process of claim 17, wherein the read/write voltage domain crossing is configured in a pull-down network of the read latch.

19. The process of claim 18, wherein the read/write voltage domain crossing is configured at the terminals of a single transistor of the pull-down network.

20. The process of claim 18, further comprising:
configuring the pull-down network on a latching node of the read latch.
